(19) United States
(12) Patent Application Publication
(10) Pub. No.: US 2010/0025720 A1
(43) Pub. Date: Feb. 4, 2010

(54) PACKAGING STRUCTURE AND METHOD FOR LIGHT-EMITTING DIODE

(76) Inventors: Soshchin NAUM, Changhua City (TW); Wei-Hung Lo, Taipei City (TW); Chi-Ruei Tsai, Taipei City (TW)

Correspondence Address: Guice Patents PLLC, 12647 Galveston Court #302, Manassas, VA, 20112, US

(21) Appl. No.: 12/506,353

(22) Filed: Jul. 21, 2009

(30) Foreign Application Priority Data
Jul. 29, 2008 (TW) 097128614

(51) Int. Cl. H01L 33/00

(52) U.S. Cl. 257/99; 257/E33.058

(57) ABSTRACT

The present invention discloses a packaging structure for light-emitting diode, which comprises a grain to provide electroluminescence; a solder paste layer disposed on the bottom and perimeter of the grain to connect the grain with at least one support; and a heat-conducting layer disposed at the bottom of the grain to work as a heat-dissipating path for the grain, so that the aforementioned structure may significantly reduce the packaging thermal resistance of light-emitting diode. Further, the present invention also discloses a packaging method for light-emitting diode, which is capable of greatly reducing the packaging thermal resistance of light-emitting diode.

### FIELD OF THE INVENTION

The present invention relates to a packaging structure and method for light-emitting diode, and in particular, to a packaging structure and method for light-emitting diode, which can significantly reduce the packaging thermal resistance of light-emitting diode.

### BACKGROUND OF THE INVENTION

Light emitting diodes (abbreviated as LED) used at present are mostly high-power light-emitting diodes (power higher than 0.5 W) and efforts are being made to package high-power light-emitting diode with low thermal resistance (high heat dissipation) because the luminous efficacy of light-emitting diodes are closely related to temperature: luminous efficacy decreases as temperature increases. Therefore, the packaging of high-power light-emitting diode is developed toward fast heat dissipation, i.e. low thermal resistance.

FIG. 1 illustrates the packaging structure of a conventional high-power light-emitting diode; as shown in the figure, the thermal resistance is divided into four parts. The first part is a light-emitting diode luminescent layer (InGaN) 100. The second part is a light-emitting diode substrate 120, which is usually sapphire (Al₂O₃). The first and the second parts are combined as a light-emitting diode grain or chip. The third part is a silver paste layer 130 connecting the light-emitting diode grain and light-emitting diode support. The fourth part is a heat-conducting layer 140 of the light-emitting diode support; the layer is usually made of copper alloy C194 and is also named as heat sink.

The equation of calculating the thermal resistance of the elements in FIG. 1 is as follows:

R=I/(S*λ),

where I is distance, S is cross-section area, and λ is the heat conductivity of the material (W/m° C.), and the results of the heat resistance of the aforementioned four parts are shown in TABLE 1.

TABLE 1

| | Luminescent | | | |
|---|---|---|---|---|
| | layer | Substrate | Silver Paste | heat-conducting |
| | (InGaN) | (Al₂O₃) | Layer | Layer |
| λ (W/mK) | 170 | 42 | 5 | 264 |
| l (mm) | 0.005 | 0.1 | 0.02 | 0.4 |
| S (mm²) | 1.0 | 1.0 | 1.0 | 7.07 |
| R (° C./W) | 0.029 | 2.38 | 4 | 0.21 |

R = 0.029 + 2.38 + 4 + 0.21 = 6.62

TABLE 1 shows that the silver paste layer 130 in the thermal resistance of the light-emitting diode packaging structure accounts for a large proportion of the total thermal resistance. Thus, the thermal resistance of light-emitting diode packaging structure can be greatly improved if a material with high heat conductivity can be found to replace the silver paste.

An available method at present is eutectic soldering, which comprises: firstly, a layer of eutectic material AuSn is applied on light-emitting diode grain, and then the light-emitting diode is placed in contact with a light-emitting diode support and is rubbed against the light-emitting diode support in an ultrasonic frequency to melt AuSn with frictional heating. The molten AuSn is cooled suddenly to attach (or connect) the light-emitting diode grain onto the light-emitting diode support. The heat conductivity of AuSn is 58 W/m° C. and its thickness is only 0.01 mm. Indeed, the thermal resistance of the layer is only 0.17° C./W, which can effectively reduce the thermal resistance of the total packaging structure. However, the cost will be enhanced by adding eutectic soldering equipment. Moreover, the eutectic material has to be firstly coated on light-emitting diode grain or chip, which is then rubbed at a large area in an ultrasonic frequency. The potential damage resulted from this frictional heating is not yet studied and thus the eutectic soldering approach is not popular.

Consequently, it is necessary to provide a packaging structure and method for light-emitting diode to overcome the shortcomings aforementioned.

### SUMMARY OF THE INVENTION

The main objective of the present invention is to provide a packaging structure for light-emitting diode, which can greatly reduce the packaging thermal resistance of light-emitting diode.

A further objective of the present invention is to provide a packaging structure for light-emitting diode, in which silver paste is replaced with solder paste to reduce the time for heating as well as to reduce cost.

To achieve the aforementioned objectives, a packaging structure for light-emitting diode according to the present invention is provided, which comprises: a grain to provide electroluminescence; a solder paste layer disposed on the bottom and perimeter of the grain to connect the grain with at least one support; and a heat-conducting layer disposed on the bottom of the grain to work as a heat-dissipating path for the grain.

To achieve the aforementioned objectives, a packaging method for light-emitting diode according to the present invention is provided, which comprises the following steps: providing a grain for electroluminescence; disposing solder paste layer on the bottom and perimeter of the grain to connect the grain with at least one support; and disposing a heat-conducting layer on the bottom of the grain to work as a heat-dissipating path for the grain.

### BRIEF DESCRIPTION OF THE DRAWINGS

The present invention can be more fully understood by reference to the following description and accompanying drawings, in which:

FIG. 1 illustrates the packaging structure of a conventional high-power light-emitting diode used at present;

FIG. 2 illustrates a preferred embodiment of a packaging structure for light-emitting diode according to the present invention; and

FIG. 3 illustrates the process of a packaging method for light-emitting diode according to another embodiment of the present invention.

### DETAILED DESCRIPTION OF THE INVENTION

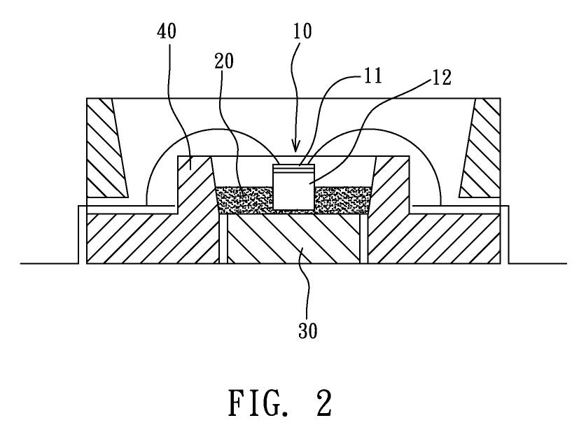

FIG. 2 illustrates a preferred embodiment of a packaging structure for light-emitting diode according to the present invention.

With reference to FIG. 2, a packaging structure for light-emitting diode according to the present invention comprises a grain 10, a solder paste layer 20, and a heat-conducting layer 30;

wherein the grain 10 is to provide electroluminescence, further comprising a luminescent layer 11 and a substrate 12, wherein the luminescent layer 11 is, for example but not limited to, an InGaN grain, which will be cited as an example for explanation in the present invention and which is not intended to limit the scope of the present invention; the substrate 12, which is, for example but not limited to, sapphire (Al₂O₃), copper alloy or monocrystal silicon, and is disposed under the luminescent layer 11 to connect the grain 10 with the solder paste layer 20. The thickness of the solder paste layer 20 may be 50˜90% of that of the grain 10, for example but not limited to 0.02 mm.

The solder paste layer 20 is disposed on the bottom and perimeter of the grain 10 to connect the grain 10 with at least one support 40, which is, for example but not limited to, the positive and negative pins of the light-emitting diode.

The heat-conducting layer 30, also named as heat sink, is disposed on the bottom of the solder paste layer 20 to work as a heat-dissipating path for the grain 10.

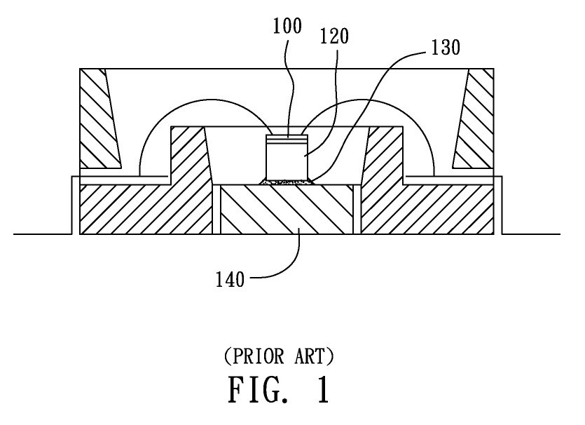

The present invention employs solder paste usually used in processing print circuit boards (both lead-containing and lead-free solder paste have the same function, but lead-free solder paste is preferred if environmental concern is taken into account) to replace the silver paste layer used in the prior art of packaging structure. This is a novel approach with two advantages: first, silver paste (130 in FIG. 1) used in prior art needs to be placed in an oven at a temperature higher than 110° C. for 90˜120 minutes or more to solidify the silver paste, in order to attach the light-emitting diode grain 10 onto the light-emitting diode support. With the solder paste used in the present invention, solder paste needs only to be heated instantly to 170˜240° C. for about 5˜15 seconds and then it can be used to attach the light-emitting diode grain 10 onto the light-emitting diode support. Using solder paste can clearly shorten the packaging process time for light-emitting diode. The second advantage is that the silver paste layer 20 has a heat conductivity of 45 W/m° C. and a thickness of about 0.02 mm, thus the thermal resistance of this layer is only 0.44° C./W. Such a low thermal resistance can greatly reduce the packaging thermal resistance, as shown in TABLE 2.

TABLE 2

| | Luminescent | | | |
|---|---|---|---|---|
| | Layer | Substrate | Solder paste | Heat-conducting |
| | (InGaN) | (Al₂O₃) | Layer | Layer |
| λ (W/mK) | 170 | 42 | 45 | 264 |
| l (mm) | 0.005 | 0.1 | 0.02 | 0.4 |
| S (mm²) | 1.0 | 1.0 | 1.0 | 7.07 |
| R (° C./W) | 0.029 | 2.38 | 0.44 | 0.21 |

R = 0.029 + 2.38 + 0.44 + 0.21 = 3.06

Consequently, the total packaging thermal resistance of light-emitting diode is reduced to 3.06° C./W, an effective reduction of total packaging thermal resistance by nearly 50%.

Further, TABLE 1 shows that when sapphire is used as the substrate 12 in the light-emitting diode grain 10, the thermal resistance is rather large. Although sapphire is transparent to visible light and thus can increase the blue light extraction efficiency of the blue light light-emitting diode grain 10, the thermal resistance of sapphire can induce substantial temperature rise and in turn decrease luminous efficacy. Therefore, some light-emitting diode grain manufacturers use materials with high heat-conductivity, copper alloy or monocrystal silicon for example, as the substrate 12 of the blue light light-emitting diode grain 10. Although materials with high heat-conductivity are not transparent (cannot be penetrated), light-emitting diode grains manufacturers would add a reflective layer (not shown) under the luminescent layer, which guides all the light generated toward the positive side (top) to greatly ameliorate the effect of non-transparency of the substrate. Consequently, the substrate 12, copper alloy (heat conductivity of 164 W/m° C.) or monocrystal silicon (heat conductivity of 146 W/m° C.) for example, used in the light-emitting diode grain 10 has a much higher heat conductivity than that of sapphire 12 (heat conductivity of 45 W/m° C.) and thus can effectively reduce the packaging thermal resistance of light-emitting diode. The details are shown in TABLE 3 and TABLE 4.

TABLE 3

| | Luminescent | Copper | Solder paste | Heat-conducting |
|---|---|---|---|---|
| | Layer (InGaN) | Alloy | Layer | Layer |
| λ (W/mK) | 170 | 264 | 45 | 264 |
| l (mm) | 0.005 | 0.1 | 0.02 | 0.4 |
| S (mm²) | 1.0 | 1.0 | 1.0 | 7.07 |
| R (° C./W) | 0.029 | 0.38 | 0.44 | 0.21 |

R = 0.029 + 0.38 + 0.44 + 0.21 = 1.06

Using copper alloy as the substrate 12 of the light-emitting diode grain 10, the total packaging thermal resistance of light-emitting diode is reduced to 1.06° C./W.

TABLE 4

| | Luminescent | | Solder | |
|---|---|---|---|---|
| | Layer | Monocrystal | paste | Heat-conducting |
| | (InGaN) | Silicon | Layer | Layer |
| λ (W/mK) | 170 | 146 | 45 | 264 |
| l (mm) | 0.005 | 0.1 | 0.02 | 0.4 |
| S (mm²) | 1.0 | 1.0 | 1.0 | 7.07 |
| R (° C./W) | 0.029 | 0.68 | 0.44 | 0.21 |

R = 0.029 + 0.68 + 0.44 + 0.21 = 1.36

Using monocrystal silicon as the substrate 12 of the light-emitting diode grain 10, the total packaging thermal resistance of light-emitting diode is reduced to 1.36° C./W.

TABLE 3 and TABLE 4 show that if the substrate 12 of the light-emitting diode grain 10 is made of material with high heat-conductivity, the solder paste layer 20 used as the connecting layer for the light-emitting diode grain 10 and light-emitting diode support 40 will contribute significantly to the total thermal resistance in light-emitting diode packaging. In such a situation, the amount of the solder paste layer 20 used can be increased to 90% of the thickness of the light-emitting diode grain 10 at most, as shown in FIG. 2.

In light-emitting diode packaging, if the thickness of the solder paste layer 20 is increased to 50˜90% of that of the light-emitting diode grain 10, the heat generated from the working of the light-emitting diode grain 10 can be dissipated into two paths: heat can pass along the original path and the path created by the additional solder paste layer 20. The equation for thermal resistance is therefore shown in TABLE 5 and TABLE 6 (wherein the upper part of the thickness of the light-emitting diode grain 10 is the common path, one path passes through the lower part of the light-emitting diode grain 10 and the solder paste layer 20 at the lower part of the light-emitting diode grain 10, and the other path is the additional part of the solder paste layer 20.).

TABLE 5

| | | | Path 1 | | Path 2 | |
|---|---|---|---|---|---|---|
| | Luminescent | | | Solder | Solder | |
| | Layer | | Copper | paste | paste | Heat-conducting |
| | (InGaN) | Copper Alloy | Alloy | Layer | Layer | Layer |
| λ (W/mK) | 170 | 264 | 264 | 45 | 45 | 264 |
| I (mm) | 0.005 | 0.05 | 0.05 | 0.02 | 0.07 | 0.4 |
| S (mm²) | 1.0 | 1.0 | 1.0 | 1.0 | 6.07 | 7.07 |
| R (° C./W) | 0.029 | 0.19 | 0.19 | 0.44 | 0.26 | 0.21 |

| | | | | |
|---|---|---|---|---|
| Equivalence | 0.029 | 0.19 | 0.18 | 0.21 |
| R (° C./W) | | | | |

R = 0.029 + 0.19 + 0.18 + 0.21 = 0.61

Using copper alloy as the substrate 12 of the light-emitting diode grain 10, the total packaging thermal resistance of light-emitting diode is reduced to 0.61° C./W.

TABLE 6

| | | | Path 1 | | Path 2 | |
|---|---|---|---|---|---|---|
| | | | | Solder | Solder | |
| | Luminescent | Monocrystal | Monocrystal | paste | paste | Heat-conducting |
| | Layer (InGaN) | Silicon | Silicon | Layer | Layer | Layer |
| λ (W/mK) | 170 | 146 | 146 | 45 | 45 | 264 |
| l (mm) | 0.005 | 0.05 | 0.05 | 0.02 | 0.07 | 0.4 |
| S (mm²) | 1.0 | 1.0 | 1.0 | 1.0 | 6.07 | 7.07 |
| R (° C./W) | 0.029 | 0.34 | 0.34 | 0.44 | 0.26 | 0.21 |

| | | | | |
|---|---|---|---|---|
| Equivalence | 0.029 | 0.34 | 0.2 | 0.21 |
| R (° C./W) | | | | |

R = 0.029 + 0.34 + 0.2 + 0.21 = 0.78

Using monocrystal silicon as the substrate 12 of the light-emitting diode grain 10, the total packaging thermal resistance of light-emitting diode is reduced to 0.78° C./W.

TABLE 5 and TABLE 6 show that if the amount of solder paste layer 20 used is increased to half thickness of the light-emitting diode grain 10, the total packaging thermal resistance of light-emitting diode can be substantially reduced by over 30˜40%, which is an effective way of reducing the total packaging thermal resistance of light-emitting diode and is also a novel design. Consequently, the packaging structure of light-emitting diode according to the present invention can indeed overcome the drawbacks of conventional light-emitting diode packaging structure.

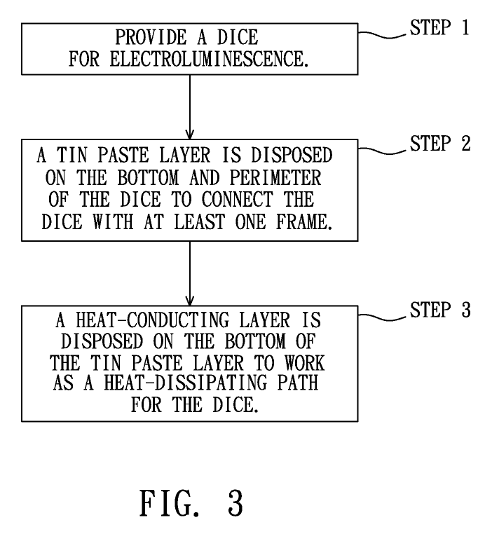

Further, the present invention also discloses a packaging method for light-emitting diode. FIG. 3 illustrates the process of a packaging method for another embodiment of light-emitting diode according to the present invention. As shown in the figure, a light-emitting diode packaging method according to the present invention comprises the following steps: providing a grain 10 for electroluminescence (step 1); disposing a solder paste layer 20 on the bottom and perimeter of the grain 10 to connect the grain 10 with at least one support 40 (step 2); and disposing a heat-conducting layer 30 on the bottom of the solder paste layer 20 to work as a heat-dissipating path for the grain 10 (step 3).

In step 1, a grain 10 is disposed to provide electroluminescence, wherein the grain 10 may provide electroluminescence and further comprises a luminescent layer 11, and a substrate 12; wherein the luminescent layer 11 is, for example but not limited to, an InGaN grain; and the substrate 12 is disposed under the luminescent layer 11 to connect the grain 10 with the solder paste layer 20, which is, for example but not limited to, sapphire (Al₂O₃), copper alloy or monocrystal silicon.

In step 2, the solder paste layer 20 is disposed on the bottom and perimeter of the grain 10 to connect the grain 10 with at least one support 40, wherein the thickness of the solder paste layer 20 may be 50˜90% of that of the grain 10, for example but not limited to, 0.02 mm, and the support 40 is, for example but not limited to, the positive and negative pins of the light-emitting diode.

In step 3, the heat-conducting layer 30 is disposed on the bottom of the solder paste layer 20 to work as a heat-dissipating path for the grain 10, wherein the heat-conducting layer 30, also named as heat sink, is disposed on the bottom of the solder paste layer 20 work as a heat-dissipating path for the grain 10.

Consequently, with the implementation of the packaging structure of light-emitting diode according to the present invention, the packaging thermal resistance of light-emitting diode can be greatly reduced; replacing the silver paste layer with the solder paste layer can reduce the heating time as well as reduce manufacturing cost. The present packaging structure for light-emitting diode can indeed overcome the drawbacks of conventional packaging structure for light-emitting diode.

It is appreciated that although the directional practice device of the present invention is used in a very limited space instead of practicing at the real playing field, effective and steady practice can be obtained as well. Further, it is very easy to set up and to operate the directional practice device of the present invention. These advantages are not possible to achieve with the prior art.

While the invention has been described with reference to a preferred embodiment thereof, it is to be understood that modifications or variations may be easily made without departing from the spirit of this invention, which is defined by the appended claims.

What is claimed is:

1. A packaging structure for light-emitting diode, comprising:
a grain to provide electroluminescence;
a solder paste layer disposed on the bottom and perimeter of the grain to connect the grain with at least one support; and
a heat-conducting layer disposed on the bottom of the grain to work as a heat-dissipating path for the dice.

2. The packaging structure for light-emitting diode as defined in claim 1, wherein the grain further comprises:
a luminescent layer to provide electroluminescence; and
a substrate disposed under the luminescent layer to connect the grain with the solder paste layer.

3. The packaging structure for light-emitting diode as defined in claim 2, wherein the luminescent layer is an InGaN grain.

4. The packaging structure for light-emitting diode as defined in claim 2, wherein the substrate is sapphire (Al₂O₃), copper alloy or monocrystal silicon.

5. The packaging structure for light-emitting diode as defined in claim 1, wherein the thickness of the solder paste layer is 50˜90% of that of the grain.

6. The packaging structure for light-emitting diode as defined in claim 5, wherein the thickness of the solder paste layer is about 0.02 mm.

7. A packaging method for light-emitting diode, comprising the following steps:
providing a grain for electroluminescence;
disposing a solder paste layer on the bottom and perimeter of the grain to connect the grain with at least one support; and
disposing a heat-conducting layer on the bottom of the grain to provide a heat-dissipating path for the grain.

8. The packaging structure for light-emitting diode as defined in claim 7, wherein the grain further comprises:
a luminescent layer to provide electroluminescence; and
a substrate disposed under the luminescent layer to connect the grain with the solder paste layer.

9. The packaging structure for light-emitting diode as defined in claim 8, wherein the luminescent layer is an InGaN grain.

10. The packaging structure for light-emitting diode as defined in claim 8, wherein the substrate is sapphire (Al₂O₃), copper alloy or monocrystal silicon.

11. The packaging structure for light-emitting diode as defined in claim 7, wherein the thickness of the solder paste layer is 50˜90% of that of the grain.

12. The packaging structure for light-emitting diode as defined in claim 11, wherein the thickness of the solder paste layer is about 0.02 mm.
